(19) United States
(12) Patent Application Publication
(10) Pub. No.: US 2021/0083164 A1
(43) Pub. Date: Mar. 18, 2021

(54) Thermoelectric Device and Refrigerant Electrical Power Generator

(71) Applicant: Matthew R. D. Havner, Shoreline, WA (US)

(72) Inventor: Matthew R. D. Havner, Shoreline, WA (US)

(21) Appl. No.: 16/571,158

(22) Filed: Sep. 15, 2019

(51) Int. Cl. H01L 35/32; H01L 35/30

(52) U.S. Cl. CPC H01L 35/32; H01L 35/30

(57) ABSTRACT

The novel concept claimed in this patent is a power generation unit that harnesses thermal energy from an external system or environment by creating a lower thermal potential across a multitude of a Thermoelectric Material or Thermoelectric Generators (TEG,) with a mechanical vapor compression refrigeration system. Includes electrical circuitry needed for system operation and harnessing and amplification of power, as well as means of mounting and reference to the external energy system.

### FIELD OF THE INVENTION

The invention relates to electrical power generation devices. More particularly, electrical power generation devices in which the primary means of power generation are Thermoelectric Materials or Thermoelectric Generators (TEG,) commonly known as “Peltier Devices or Modules.”

### BACKGROUND

As Earth's population grows the demand for electrical power rises with it. Many means of generating and harvesting electrical power have been discovered and are used today. Use of fossil fuels still dominates this industry but other methods, such as solar, wind, and wave power generation have become common part in worldwide power generation. With the growing use of electric power, the more diverse the methods of power generation the better for individuals and commercial power providers.

One form of power generation that is becoming more prevalent is the use of Thermoelectric Generators (TEG.) TEG are solid state electric devices that harness thermal energy. TEG make use of the “Seebeck Effect,” discovered by Thomas Seebeck in 1821. Seebeck discovered that thermal energy applied across dissimilar conductors will produce electricity, more specifically that the thermal gradient in a conductor(s) causes a diffusion of charge carriers between the different thermal regions in said conductor(s).

Currently most devices marketed that use TEG are devices that harness secondary waste heat from other mechanical and chemical processes. There are also primary power production devices that create their thermal gradient using production of heat by chemical reaction (the burning of petroleum products or gasses, wood burning, etc.)

With a regular source of thermal energy, created in a way that was renewable and not harmful to the environment, that also provided a large enough potential to create a usable amount of power worth investing in, TEG could be a more viable option for electrical power generation.

One of the most common devices used to manipulate thermal energy seen today are mechanical vapor compression refrigeration and heating systems (air conditioning units, refrigerators, etc.) Developed throughout the 1800's by multiple scientists and inventors, research lead to the invention of modern refrigerants and systems using the like by the early 1900's. They operate on the principal that a change in state of a substance coincides with it to absorbing or rejecting thermal energy. Modern refrigerants have been designed chemically to cause as little harm to the environment as possible. Typical vapor compression refrigerant systems use a mechanical compressor to enact the changes in state in the refrigerant needed for system operation. These compressors typically use an electric motor as their prime mover and have also become more efficient over time.

Some of the more modern refrigeration compressors are efficient enough that the power required by the compressor is a fraction of the amount of thermal energy or power available by the refrigerant being compressed.

### BRIEF SUMMARY OF THE INVENTION

The novel concept claimed in this patent is a power generation unit that harnesses thermal energy from an external system (the environment, earth,) by creating a lower thermal potential across a multitude of a Thermoelectric Material or Thermoelectric Generators (TEG,) with a mechanical vapor compression refrigeration system.

### BRIEF SUMMARY OF FIGURES AND DRAWINGS PROVIDED

FIG. 1—An example of a system schematic for the combined refrigeration system and electrical circuitry.

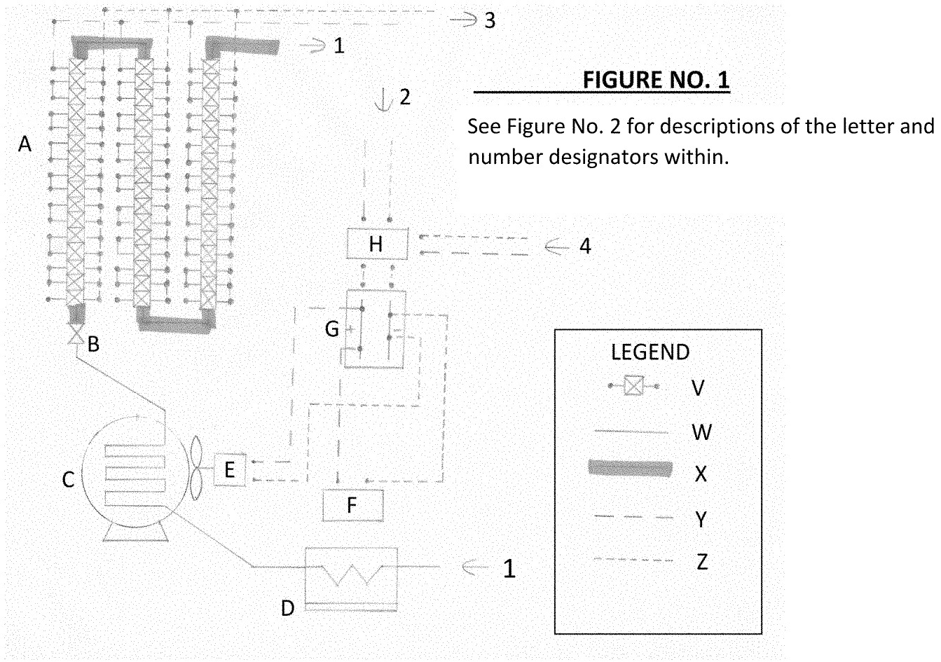

FIG. 2—Descriptions and legend for the notations in FIG. 1.

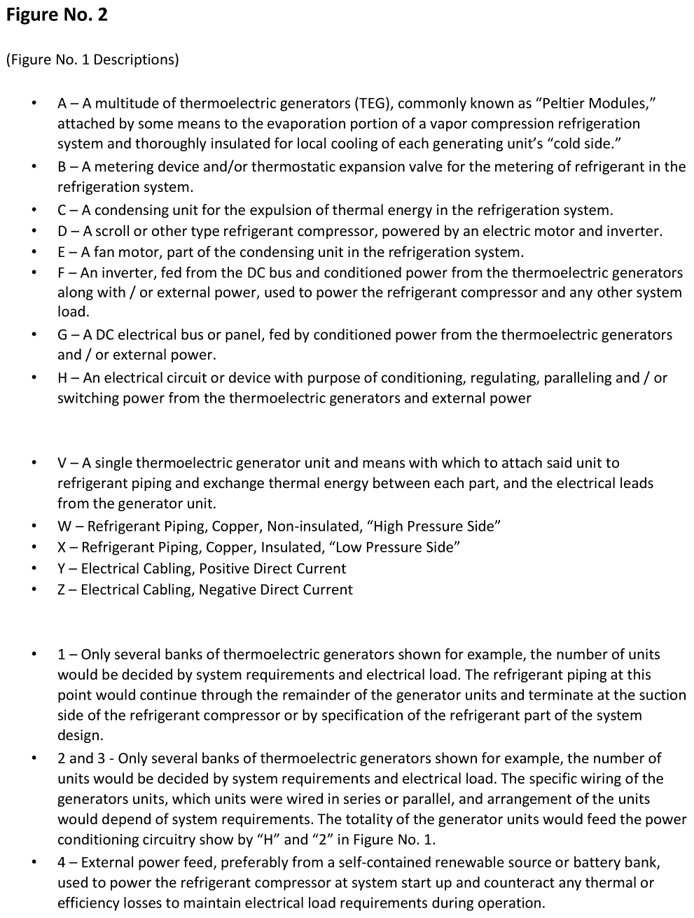

FIG. 3—Multiple views of an example method of how a single TEG module would be attached to the refrigerant system piping and heat sink, along with the insulation necessary.

### DETAILED DESCRIPTION OF THE INVENTION

The language and nomenclature used throughout this document and description are for illustration of concepts and embodiments only and is not intended to be limiting of the invention and its variable unit and system designs, specifications, applications, and additions. Electrical and refrigeration systems can be engineered to a vast range of uses and specifications and therefore the following description, figures, and drawings provided are for exemplification of the general purpose and construction of the device. Additional components, parts, and safety devices necessary in final design are assumed as the invention is composed of separate parts and devices that are of common knowledge to those skilled in the applicable arts from which they are derived.

The layout and physical design of the invention could be tailored to any use if all necessary parts were included. Means of storage, mounting, and transportation are assumed in design. The use of the terms “and/or,” “including, but not limited to,” and the like are assumed to include any possible variations and designs.

As stated above, the novel concept claimed in this patent is a power generation unit that harnesses thermal energy from an external system (the environment, earth,) by creating a lower thermal potential across a multitude of a Thermoelectric Material or Thermoelectric Generators (TEG,) with a mechanical vapor compression refrigeration system.

The unit generally consists of a multitude of Thermoelectric Material or Thermoelectric Generators (TEG,) [used interchangeably in this document] commonly known as “Peltier Modules,” a refrigeration system (TEG Mounted Evaporator, Compressor, Condenser, Thermal Expansion Valve, all other needed system components,) and the electrical circuitry necessary for the harvesting of electrical energy from the TEG and operation of the unit itself. Means of creating a thermal gradient across the TEG are also included, particularly, but not limited to, insulation of one portion of the TEG with the evaporator of said refrigeration system from ambient temperature, and reference to ambient temperature or a heat source for the opposing portion of the TEG, by means of a heat sink or otherwise.

During normal operations the multitude of TEG would harness energy from an external system of a higher thermal potential and discharge to an external load as well as provide power for the refrigeration system and any other system load. Included circuitry would require a connection to a battery bank or external power source to provide power during start-up of the unit, as the Thermoelectric Material was brought to temperature.

The remainder of the electrical circuitry and/or devices include, but is not limited to: means of multiplying or amplifying the power provided by the TEG, raising or boosting potential, rectifying the external power source or inverting the TEG power depending on system design, regulating voltage from the external power source, regulating voltage from the multitude of TEG, paralleling and/or switching TEG (system) power and external power, distribution of power to the external load and system load, and inverting power to any alternating current refrigeration system devices.

Selection of Thermoelectric Material, or TEG modules, and the quantity and wiring thereof must be based on combined external and system power requirements. The maximum power output of the combined TEG during normal operation at the greatest thermal gradient maintainable within the limitations of the refrigeration system must be equal to or greater than the combined desired external load and required system load. The number of individual TEG wired in series or parallel with the remainder of the TEG depends on the TEG current capacity and voltage requirements of the regulation circuitry. The wiring of the TEG in the figures provided is solely for example.

The refrigeration system portion of the invention differs little from modern refrigeration systems seen in heating, ventilation, air conditioning, and refrigeration trades. The system would use a typical cycle of compression, condensation, expansion, and evaporation. The evaporation stage of the refrigerant providing the cooling for the multitude of TEG. To create the largest possible thermal gradient, system design should include, but is not limited to, use of “low temperature” refrigerant. The refrigeration system consists, but is not limited to, an electric motor driven refrigerant compressor, a condenser unit, a fan and motor for the condenser unit, a metering device or thermostatic expansion valve, copper piping to interconnect said parts and for the mounting of the TEG, and insulation of certain parts of said piping. Any additional refrigeration system parts required that are of common knowledge to those skilled in applicable art (filters, driers, receivers, etc.) are assumed.

Selection of the proper refrigerant compressor is necessary for the system to function properly and meet external and system load requirements. The total thermal capacity of the compressor must be equal to or greater than the maximum power requirements of the external and system loads including the compressor's own power. An inverter powered “scroll” type refrigerant compressor is shown for example in the figures provided.

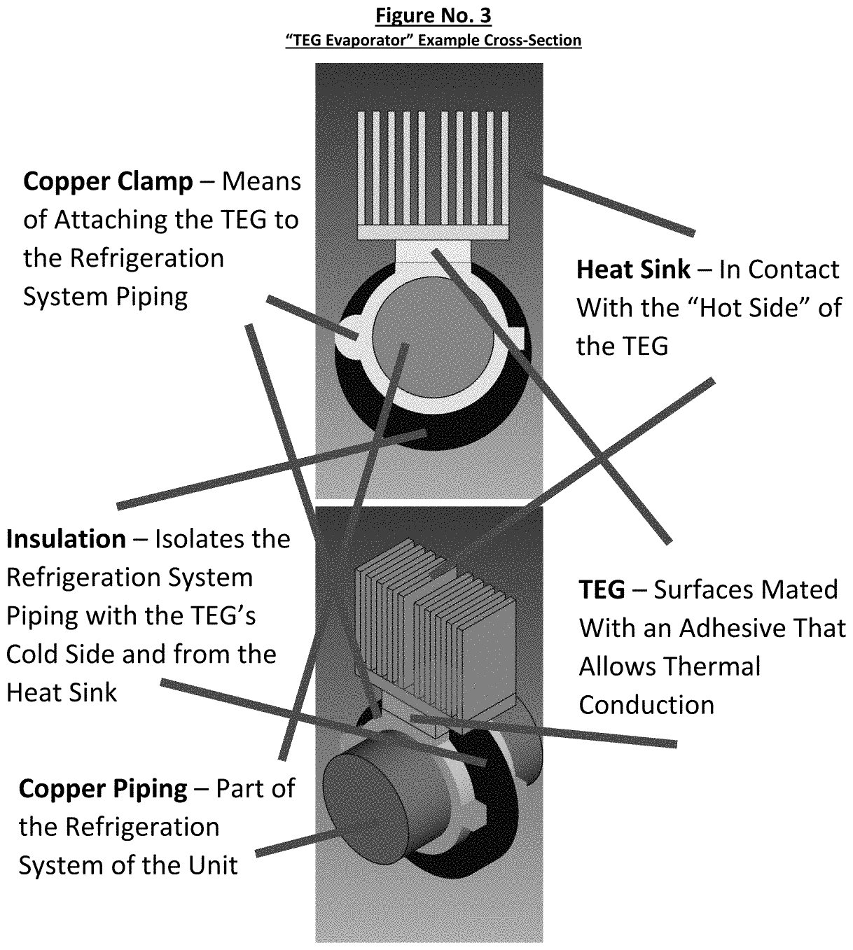

The section of copper piping between the thermal expansion valve and the compressor, where the evaporation stage of the refrigeration cycle occurs, is where multitude of TEG are mounted (further referred to as the TEG Evaporator.) Mounting means must be in a manner that allow thermal conduction between the refrigerant piping and the “cold side” of each TEG and allow separation and space for mounting of a heat sink to the opposite, “hot side” of each TEG. See FIG. 3 for example. The example shows an individual TEG mounted to the refrigeration piping on a copper clamp. Any sealants or compounds for mating surfaces of the TEG would need to allow for thermal conduction.

The diameter, length, and layout of the copper piping in this segment of the refrigeration system is dependent of the number of TEG that are to be attached due to electrical specifications, and the amount of refrigerant needed in system design for the calculated thermal load. This section of the system must be thoroughly insulated. Partially to minimize the volume being cooled by the refrigeration system, ideally just the piping and the one “cold side” surface of each TEG to maximize efficiency. Also, to isolate the two sides of each TEG for maximum thermal gradient. Insulation must allow access to the electrical conductors for wiring of the TEG.

The metering device or thermostatic expansion valve (TXV) is adjusted for maintenance of steady pressure in the TEG evaporator to sustain as stable as possible temperature for any given electrical load. Adjustment of the TXV, the absence of TEG in planned excess piping in the TEG evaporator, secondary metering means, or an uninsulated section of the TEG evaporator may be necessary for proper refrigerant state exiting the TEG evaporator and/or entering the compressor.

The condenser must be sized to exchange the refrigeration systems “total heat of rejection.” The condenser may be a free-standing part of unit design or encompassed. Unit design may include, but is not limited to, means of channeling air blown through the condenser coil by the condenser fan to the heat sinks of the TEG to increase the thermal gradient across the TEG. This would have to be done in a manner that increased economy of the unit, namely the insulating of this air passing from the condenser to separate it from the “cold side” of the TEG and the refrigeration piping.

The condenser fan and motor may be included with the condenser or assembled alongside or atop the condenser in unit design. Fan and motor selection must allow for maximum electrical efficiency while expelling the necessary thermal energy from the condenser. In overall unit layout and design, separation, isolation, and/or insulation of the condenser from the TEG evaporator is desired for maximum efficiency.

A typical veined heat sink seen in use with “Peltier Modules” is show in the example in FIG. 3 but system design is not limited to this means of reference to ambient temperature or area of higher thermal potential.

1. An electrical power generation device, that harnesses thermal energy from an external system (environment) by creating a comparatively lower thermal potential across a multitude of any Thermoelectric Material or Thermoelectric Generator, with a mechanical vapor compression refrigeration system, and any circuitry, materials, or components needed to operate the device.
